(19) United States
(12) Patent Application Publication
(10) Pub. No.: US 2023/0345669 A1
(43) Pub. Date: Oct. 26, 2023

(54) Heat-Absorbing Chassis For Fan-Less Electronic Component

(71) Applicant: Quanta Computer Inc., Taoyuan City (TW)

(72) Inventors: Yi-Chieh CHEN, Taoyuan City (TW); Yueh-Chang WU, Taoyuan City (TW); Te-Chuan WANG, Taoyuan City (TW); Po-Kai TSENG, Taoyuan City (TW)

(21) Appl. No.: 17/659,977

(22) Filed: Apr. 20, 2022

(51) Int. Cl. H05K 7/20; G06F 1/20

(52) U.S. Cl. CPC H05K 7/20263; H05K 7/20254; G06F 1/20

(57) ABSTRACT

A heat transmissive chassis for a fan-less equipment component such as a 5G component is disclosed. The chassis includes a heat sink section having an interior surface and an exterior surface. The interior surface is configured for contact with a heat-generating electronic device. A lateral hollow compartment is located near the interior surface. A coolant is contained in the hollow compartment.

### TECHNICAL FIELD

The present disclosure relates generally to cooling for 5G components. More particularly, aspects of this disclosure relate to a heat-absorbing chassis with a chamber for liquid coolant.

### BACKGROUND

The fifth generation of mobile communication technology (5th generation wireless systems, referred to as 5G) is the latest generation of mobile communication technology. The 5G technology is an extension of legacy 4G (LTE) mobile communication systems. The recent roll out of the 5G communication infrastructure has required the deployment of 5G capable components. The previous 4G system required a baseband unit (BBU), a remote radio unit (RRU), and an antenna to allow for communications between mobile devices. 5G systems for communication between mobile devices have higher speeds, lower latency, and larger Bandwidths, allowing for more connections and for more data to be processed. Such capabilities are possible through fan-less components such as radio units (RU), centralized units (CU), distributed units (DU), and active antenna units (AAU). In 5G systems the functions of the BBU in 4G systems are performed by the distributed units and centralized units, and the functions of the antenna and the RRU in 4G systems are performed by the active antenna units.

Compared with 4G, the increased transmission speed of 5G requires more components that generate greater heat. The area of heat dissipation components, such as heat sinks and fins in 5G equipment must be increased to allow 5G operation. For example, 5G base stations have 2-3 times the power consumption of 4G base stations. Higher power consumption results in greater heat generation. If a 5G base station has poor heat dissipation, work efficiency is reduced, and equipment problems such as damage, crashes, and disconnection of the network may result seriously affecting user experience.

5G DUs and AAUs are components that are typically located in outdoor environments. Outdoor electronic chassis design for DUs and AAUs requires being waterproof, dustproof, and anti-corrosive. Therefore, the chassis for 5G outdoor components is designed as a closed system and the chassis is usually designed as a heat sink to cool the electronic devices in such components. Such thermal solutions are thus a fan-less design.

The traditional chassis thermal solution of an outdoor component is divided into an inner thermal solution and an outer thermal solution. The inner thermal solution, such as a heat-pipe or a vapor chamber, may be part of the chassis. A heat-pipe or vapor chamber allows heat generated from the electronic devices to spread making the inner chassis reach a uniform temperature that can enhance thermal performance. The outer thermal solution is typically an external fin structure built on the chassis, which can dissipate heat generated by the component to ambient air.

Standard heat-pipes only transfer heat along the axis of the heat-pipe, so they are best suited to cooling discrete heat sources. Vapor chambers or high conductivity (HiK™) plates are essentially two dimensional heat pipes that are used to collect heat from larger area sources. A vapor chamber either spreads the heat over a large surface are or conducts the heat to a cold rail for cooling. Vapor chambers are generally used for high heat flux applications, or when genuine two-dimensional heat spreading is required. Vapor chambers function similar with heat-pipes but the thermal conduction mode of the heat-pipe is one-dimensional, while the vapor chamber is two-dimensional, so that the vapor chamber performs the traditional function of heat transfer from the heat source to the cooling area, but also allows for rapid heat diffusion. Vapor chamber thermal performance is better than that of a heat-pipe, but vapor chambers require greater area and are generally more costly.

Referring generally to FIGS. 1A and 1B, a prior art fan-less system provides inefficient and/or insufficient heat transfer for a telecommunications component 10, which is an 5G distributed unit (DU) in this example. FIG. 1A shows an exterior view of the component 10 and FIG. 1B shows a cross section of the component 10. The prior art fan-less component 10 includes a chassis housing 20 that encloses a printed circuit board 22. The chassis housing 20 includes a panel 24 that provides entry points for connectors and cables 26. A thick heat sink section 30 of the chassis housing 20 serves as a large chassis heat sink that encloses the printed circuit board 22. The heat sink section 30 has an interior surface 32, and an exterior surface 34 that supports a series of cooling fins 36. The cooling fins 36 provide increased surface area to dissipate heat to the ambient air. Heat is absorbed by the interior surface 32 and transferred through the heat sink 30 to the cooling fins 36 to be dissipated in ambient air. The chassis housing 20 thus is fabricated from a heat conductive material such as aluminum or aluminum alloy.

The printed circuit board 22 that includes electronic devices such as a processor 40. In this example, the processor 40 is in thermal contact with the interior surface 32 of the heat sink section 30 of the chassis 20. Thus, in the fan-less system, heat generated by the processor 40 is transferred to the heat sink section 30 to dissipate the heat.

Unfortunately, the traditional chassis design in FIGS. 1A-1B does not spread the generated heat very well without an internal thermal solution. This is because the thermal conductivity of such a chassis alone is around 160 W/mK. In order to improve thermal conductivity, a heat-pipe or vapor chamber may be deployed on the interior surface of the chassis 20 to achieve uniform temperature inside the chassis. The compact thermal conductivity of a heat-pipe is around 12000 W/mK, while that of a vapor chamber is around 6000 W/mK, which are both higher than the thermal conductivity of the chassis material alone. In order to implement a heat-pipe or vapor chamber in a chassis, the chassis requires additional manufacturing steps to be accommodate heat-pipes or a vapor chamber chassis. The process of manufacturing to allow the heat-pipes to be accommodated is very complex and the thermal conductivity yield rate of the chassis may be impacted.

FIGS. 1C-1D show the implementation of heat-pipes in another prior art chassis 50 that has additional heat dissipation. FIG. 1C shows a cutaway view of the chassis 50 and FIG. 1D shows a cross section of the chassis 50. The chassis 50 has an interior surface 52 and an exterior surface 54 with cooling fins 56. The chassis 50 encloses a printed circuit board 60 with a processor 62. The interior surface 52 includes a series of grooves 64 that are machined for insertion of a network of heat-pipes 70. The series of heat-pipes 70 each have sections that are in proximity to the processor 62 and other sections that allow heat to be conveyed away from the processor 62. The chassis 50 has the same general function as the chassis 20 in FIG. 1B, but has greater thermal conductivity due to the inclusion of the heat-pipes 70 to transmit heat from the processor 62 over the area of the interior surface 52.

Although the chassis 50 results in better thermal conductivity, the footprint of the chassis 50 must be increased when using the heat-pipes 70 as an inner thermal solution. As shown in FIG. 1D, the chassis 50 needs to have enough thickness based on thermal performance consideration and manufacturing limitations for machining the grooves 64 for holding the heat-pipes 70. However, a greater thickness of the chassis 50 causes higher thermal resistance which will impact thermal performance. Alternatively, a vapor chamber may be inserted over the surface area of the interior surface 52 thus eliminating the need for creating the grooves 64. However, a vapor chamber still adds to the overall height of the chassis and is more expensive than the heat-pipes. Further, since vapor chambers have relatively larger sizes, yield rate may be an issue due to manufacturing capacities. Further, it is difficult to control the flatness of the surface of the vapor chamber that contacts the heat generating chip.

Thus, there is a need for an internal heat solution for an equipment chassis. There is also a need for an internal heat solution that does not require a thicker heat sink section of an equipment chassis. There is also a need for an effective heat absorbing chassis that is simple to manufacture.

### SUMMARY

One disclosed example is a thermally absorbing chassis operable to enclose electronic components. The chassis includes a heat sink section having an interior surface and an exterior surface. The interior surface is configured for contact with a heat-generating electronic device. A lateral hollow compartment is formed near the interior surface. A coolant is contained in the hollow compartment.

A further implementation of the example chassis is where the chassis includes cooling fins extending from the exterior surface of the heat sink section. Another implementation is where the heat sink section includes a plate soldered over a groove together to define the hollow space and the interior surface. Another implementation is where the plate is a first thermally conductive material and the heat sink section is a second, different thermally conductive material. Another implementation is where the coolant is one of water or refrigerant. Another implementation is where the heat sink section is fabricated from aluminum or an aluminum alloy. Another implementation is where the hollow compartment has opposite ends. One of the opposite ends is located near a section of the interior surface that contacts the heat generating device. Another implementation is where the electronic components are for operation of a 5G mobile communication system.

Another disclosed example is an electronic component including a printed circuit board having a heat-generating device. The example component includes a chassis enclosing the printed circuit board. The chassis has side walls, a base supporting the printed circuit board, and a heat sink section. The heat sink section includes an interior surface in thermal contact with the heat-generating device, an opposite exterior surface, and a chamber holding coolant in proximity to the interior surface.

A further implementation of the example electronic component is where the chassis includes cooling fins extending from the exterior surface of the heat sink section. Another implementation is where the heat sink section includes a plate soldered over a groove together to define the chamber and the interior surface. Another implementation is where the plate is a first thermally conductive material and the heat sink section is a second, different thermally conductive material. Another implementation is where the coolant is one of water or refrigerant. Another implementation is where the heat sink section is fabricated from aluminum or an aluminum alloy. Another implementation is where the compartment has opposite ends. One of the opposite ends is located near a section of the interior surface that contacts the heat generating device. Another implementation is where the heat generating component is for operation of a 5G mobile communication system.

Another disclosed example is a method of fabricating a heat absorbing chassis for a fan-less component. A heat sink block having an interior surface and an exterior surface is fabricated. A groove is formed in the interior surface. A plate is attached over the groove to form an interior compartment. The interior compartment is filled with coolant.

A further implementation of the example method is where fabricating of the heat sink block is performed via die casting. The heat sink block includes fins attached to the exterior surface. Another implementation is where the coolant is one of water or refrigerant. Another implementation is where the heat sink block is aluminum or an aluminum alloy and the plate is copper.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims.

### BRIEF DESCRIPTION OF THE DRAWINGS

The disclosure will be better understood from the following description of exemplary embodiments together with reference to the accompanying drawings, in which:

FIG. 1A is a perspective view of a prior art telecommunications component chassis;

FIG. 1B is a cross-section view of the prior art telecommunications component chassis in FIG. 1A;

FIG. 1C is a perspective view of a prior art telecommunications component chassis with embedded heat-pipes;

FIG. 1D is a cross-section view of a prior art telecommunication component chassis with embedded heat-pipes;

FIG. 2A shows a perspective cutaway view of the example chassis with improved heat dissipation for a telecommunications component, according to certain aspects of the present disclosure;

FIG. 2B shows a cross-section view of the example chassis in FIG. 2A, according to certain aspects of the present disclosure;

FIG. 2C shows a top view of the example chassis in FIG. 2A relative to a printed circuit board, according to certain aspects of the present disclosure;

FIG. 3 shows the process of manufacturing the example chassis in FIG. 2A, according to certain aspects of the present disclosure; and

FIG. 4 shows a cross-section view of the example chassis when deployed in a typical outdoor environment, according to certain aspects of the present disclosure.

The present disclosure is susceptible to various modifications and alternative forms, and some representative embodiments have been shown by way of example in the drawings and will be described in detail herein. It should be understood, however, that the invention is not intended to be limited to the particular forms disclosed. Rather, the disclosure is to cover all modifications, equivalents, and alternatives falling within the spirit and scope of the invention as defined by the appended claims.

### DETAILED DESCRIPTION OF THE ILLUSTRATED EMBODIMENTS

The present inventions can be embodied in many different forms. Representative embodiments are shown in the drawings, and will herein be described in detail. The present disclosure is an example or illustration of the principles of the present disclosure, and is not intended to limit the broad aspects of the disclosure to the embodiments illustrated. To that extent, elements and limitations that are disclosed, for example, in the Abstract, Summary, and Detailed Description sections, but not explicitly set forth in the claims, should not be incorporated into the claims, singly or collectively, by implication, inference, or otherwise. For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at, near, or nearly at,” or “within 3-5% of” or “within acceptable manufacturing tolerances,” or any logical combination thereof, for example.

The present disclosure relates to an example chassis with improved heat dissipation for electronic equipment deployed in an outdoor environment. The example chassis includes a chamber that is filled with a flowable liquid such as a coolant liquid to spread the heat evenly throughout the chassis. A coolant may be refrigerant (e.g., R1233zd) or water. The example chassis has a simple manufacturing process and better thermal performance for fan-less cooling. The example chassis eliminates the need for internal thermal devices, such as heat-pipes or a vapor chamber to improve thermal conductivity.

The example chassis simplifies the manufacturing process as specialized machining is not required for embedding heat-pipes or a vapor chamber into the chassis. The example chassis design is also less thick than conventional chassis designs having heat-pipes, resulting in a more compact equipment footprint. The example chassis has lower thermal resistance and better thermal performance than known fan-less cooling designs.

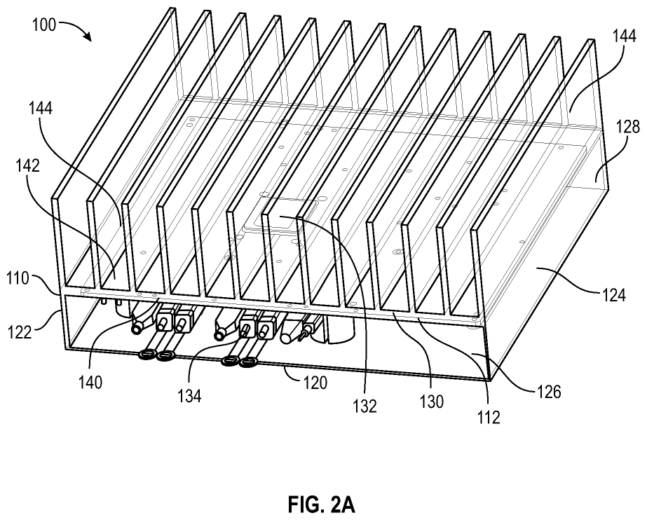

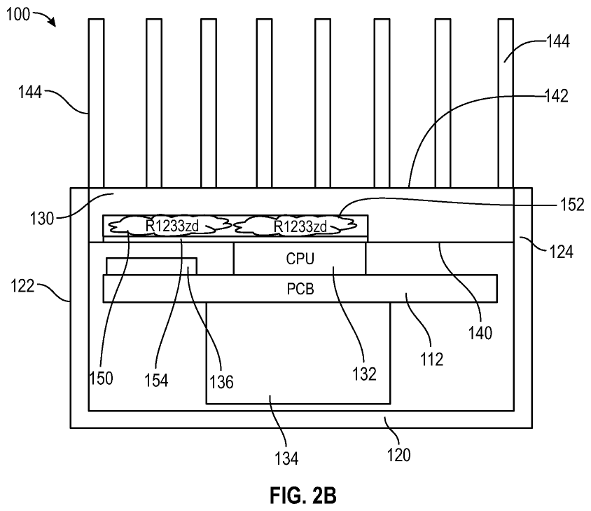

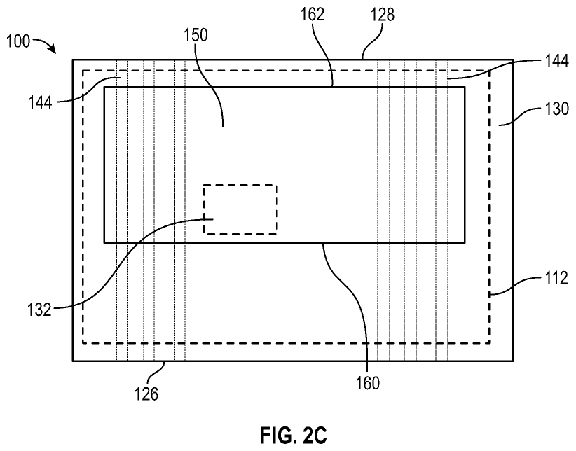

Referring generally to FIGS. 2A-2C, a fan-less communication equipment component 100 is shown. In this example, the component 100 is a 5G distributed unit (DU) that includes a chassis 110, which holds a printed circuit board 112. FIG. 2A shows a perspective cutaway view of the example component 100, FIG. 2B shows a cross-section view of the example chassis 110, and FIG. 2C shows a top view of the example chassis 110 relative to the printed circuit board 112. The example heat absorbing chassis 110 may be employed in any equipment such as other 5G telecommunication components (such as a radio unit (RU), or an active antenna unit (AAU)) that relies on a fan-less cooling system to cool its internal electronics. In this example, the DU component 100 is part of a 5G mobile communication system that relies on electronic components that require heat dissipation for proper operation.

The chassis 110 includes a base plate 120, a pair of side walls 122 and 124, a connector panel 126, and an opposite panel 128. Connection cables and connectors may be mounted to the connector panel 126 to provide power and signals to the printed circuit board 112. A heat sink section 130 is located opposite the base plate 120 and serves to enclose the printed circuit board 112. The heat sink section 130 allows transmission of heat generated by the internal electronics of the component 100 to the ambient exterior environment.

The printed circuit board 112 is mounted in close proximity to the heat sink section 130 and is suspended above the base plate 120. The printed circuit board 112 supports various electronic components performing functions for 5G communications. Thus, the printed circuit board 112 will typically include a processor, such as a CPU 132, double data rate (DDR) memory, physical layer key generation circuits, network interfaces, and other components. The opposite side of the printed circuit board 112 from the CPU 132 may hold connectors such as small form-factor pluggable (SFP) optical and RJ45 type connectors 134. The printed circuit board 112, according to the illustrated example, thus has other components 136 that generate heat, which may also be absorbed by the chassis 110.

The chassis heat sink section 130 has a generally flat interior surface 140 that absorbs heat that is transmitted through the heat sink section 130 to an opposite exterior surface 142. A part of the interior surface 140 serves as a contact surface in thermal communication with components on the circuit board 112 such as the CPU 132. A series of vertical fins 144 extend from the exterior surface 142. The vertical fins 144 increase the surface area available to dissipate heat from the chassis heat sink section 130 to the ambient environment.

The interior surface 140 includes a hollow compartment 150 that is formed over the area of the interior surface 140 that contacts heat generating components, such as the CPU 132. In this example, the hollow compartment 150 contains coolant 152, such as water or refrigerant. In this example, the coolant may be water or a refrigerant such as R1233zd. Refrigerants generally have higher thermal performance than water. In this example, the hollow compartment 150 has a rectangular shape and is preferably formed over the section of the interior surface 140 that contacts heat generating components, such as the CPU 132.

The hollow compartment 150 is created in the heat sink section 130. A plate 154 covers the hollow compartment 150 and is soldered in place to create a liquid-tight seal. The walls of the hollow compartment 150 and the plate 154 contain the coolant 152. In this example, the plate 154 is fabricated from a more heat conductive material such as copper to facilitate heat transfer, while the heat sink section 130 is fabricated from a less heat conductive material, such as aluminum or an aluminum alloy. Alternatively, both the plate 154 and the rest of the heat sink section 130 may be fabricated from the same material. Alternatively, the plate and the heat sink section 130 may be fabricated as a single piece that does not require soldering.

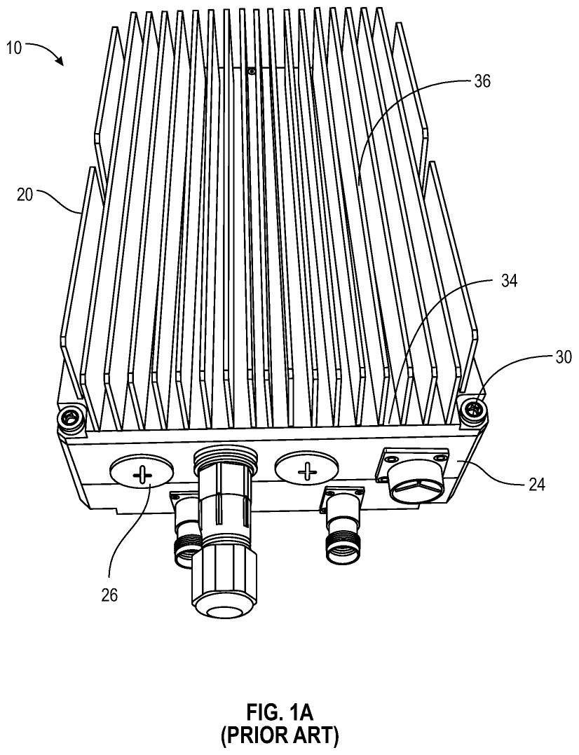

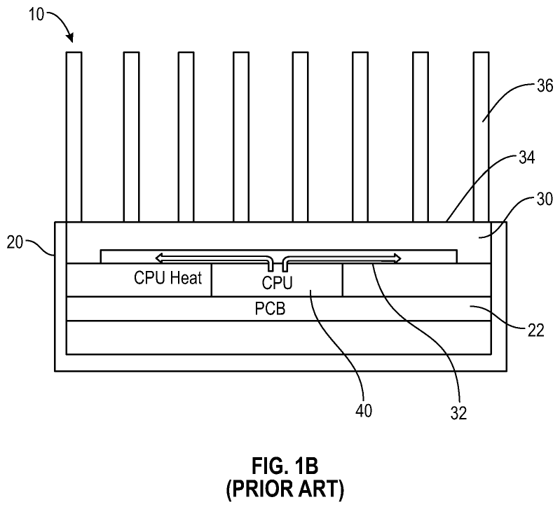

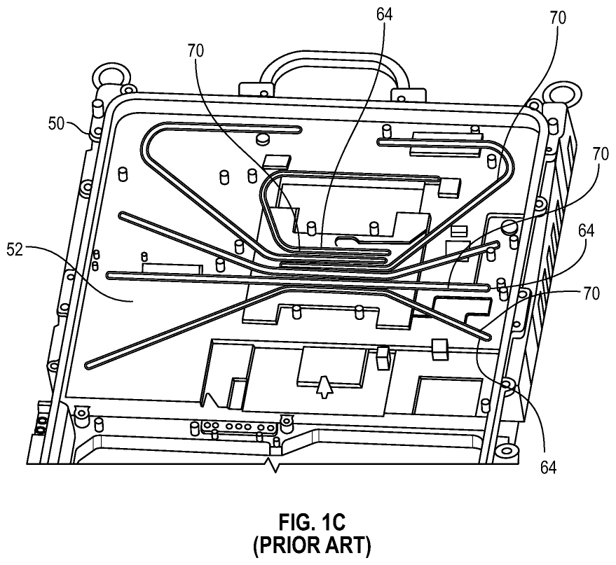

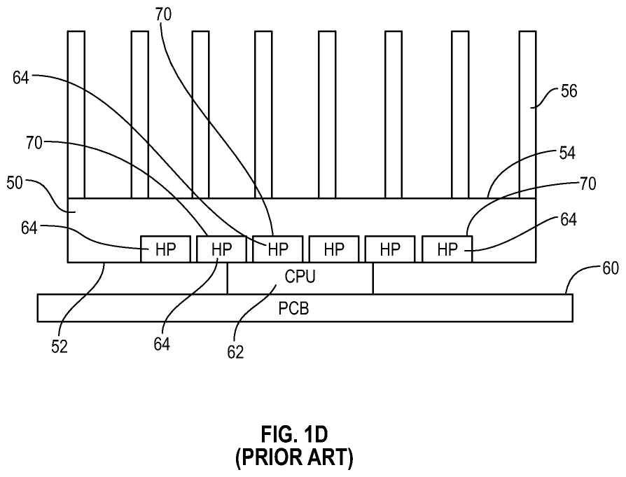

The height of the heat sink section 130 is less than the height of a known chassis that has additional structure, such as a groove network to hold heat-pipes. For example, the plate 154 may have a height of 1.5 mm, while the hollow compartment 150 has a height of 3.0 mm and the remaining part of the heat sink section 130 has a height of 3.5 mm for a total height of 8 mm for the heat sink section 130. In contrast, the height of the known chassis 50 in FIG. 1C-1D is 11.2 mm. In this manner, heat transmission is maximized by minimizing the resistance of the material of the heat sink section 130.

The heat sink section 130 of the chassis 110 does not require a capillary structure to reflow the coolant 152. In this example, the compartment 150 has an end 160 that is proximate to the CPU 132 and an opposite end 162. However, the lack of a capillary structure means that the performance may decrease by the influence of gravity when the component 100 is installed vertically.

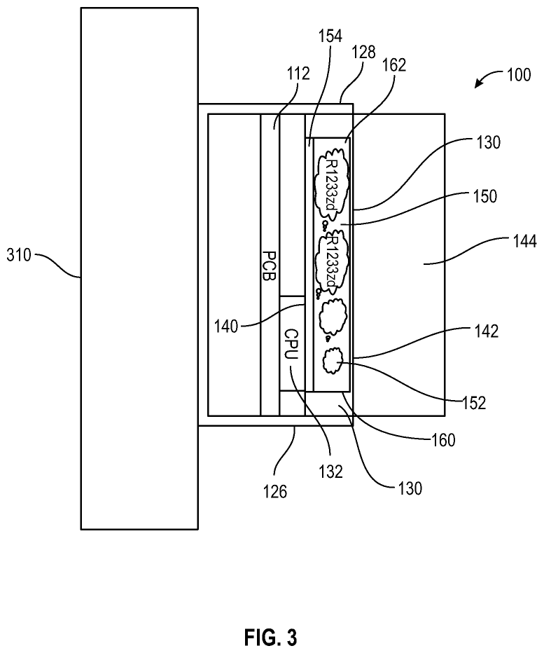

For example, FIG. 3 shows a cross section of the component 100 mounted in a vertical position on a support structure 310. The support structure 310 may be a pole or a building exterior, or other support structure. The component 100 is generally mounted on the support structure 310 with the fins 144 being exposed in an outdoor environment. Like elements in FIG. 3 are labeled with identical reference numbers as their counterparts in FIGS. 2A-2B. In this example, the component 100 is mounted in a vertical position with the connector panel 126 facing downward. The component 100 is mounted so the heat generating element, the CPU 132 is nearer the bottom of the component 100. Thus, the end 160 of the hollow compartment 150 is located in proximity to the main heat source with the highest power dissipation. In this arrangement, the coolant 152 generally pools at the end 160 of the hollow compartment 150 in proximity to the CPU 132 due to gravitational force. Due to this arrangement, the main heat source, such as the CPU 132 and the coolant 152 are at roughly the same height to ensure that the thermal dissipation performance of the coolant 152 is maintained. In normal operation, the coolant 152 at the end 160 is vaporized by the heat from the CPU 132, the vapor rises to the end 162, where it condenses and falls back to the end 160 from gravitational force. The heat is primarily dissipated by the efficient coolant 152 and the fins 144 that are exposed to ambient exterior air. It is understood that the equipment component 100 may be oriented in other directions in an operating environment.

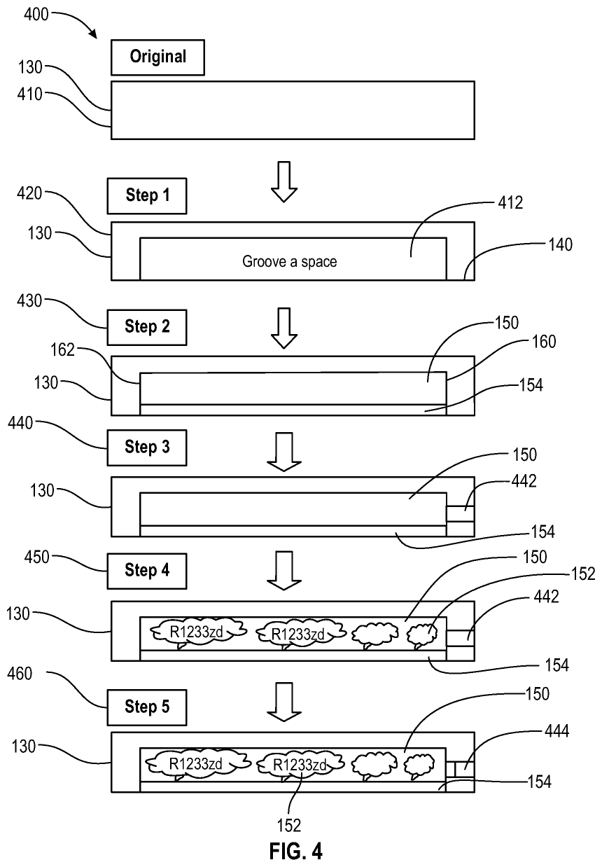

FIG. 4 shows a manufacturing process 400 for fabricating the chassis 110 in FIG. 2A-2B. In this example, the chassis heat sink section 130 is die cast with the corresponding fins (not shown) (410). In this example, the chassis heat sink section 130 is die cast fabricated from aluminum alloy, such as EN44300, but other alloys such as ADC6 or ADC10, or any similar material may be used based on thermal conductivity. In a first step 420, a groove 412 is formed into the section 130 on the interior surface 140 to form the hollow compartment 150 via a computer numerical controlled (CNC) machine tool. In this example, the groove 412 has a rectangular shape that has a smaller area than the interior surface 140. Of course, other non-rectangular shapes may be formed for the groove 412. Instead of forming the groove 412, the groove 412 may be formed by the die casting of the heat sink section 130.

In a second step 430, the plate 154 is inserted to cover the groove 412 and define the interior surface 140. In this example, the plate 154 is a comparatively more thermal conductive material such as copper than the material of the heat sink section 130. The plate 154 may also be made of aluminum or aluminum alloys such as Al 1050 or Al 6063. The plate 154 may be soldered to the sides of the groove 412 that define the ends 160 and 162 of the compartment 150. In a third step 440, a fill hole 442 is drilled into the side of the heat sink section 130 adjacent to the groove 412. In a fourth step 450, the coolant 152 is infused to the hollow compartment 150 through the fill hole 442. In a fifth step 460, the fill hole 442 is sealed via soldering to create a plug 444. Thus, the coolant 152 cannot escape from the hollow compartment 150 and is thus contained within the hollow compartment 150. The completed chassis 110 may be assembled with the other parts of the telecommunications component 100.

A thermal simulation demonstrates that the thermal performance of the chassis 110 in FIGS. 2A-2B is superior to that of known chassis designs with either heat-pipes or a vapor chamber. In the simulation, a component size of 385×420×120 mm was simulated. Thus, the simulation assumes the chassis 110 has an overall height of 120 mm including the fins 144 in FIG. 2A. A known base chassis with heat-pipes had a thermal conductivity of 12000 W/mK with a CPU temperature of 79.6 C. A known base chassis and vapor chamber had a thermal transmissibility of 6000 W/mK with a CPU temperature of 77.6 C. The simulation showed that the example chassis 110 had a thermal conductivity of 12000 W/mK with a CPU temperature of 75.7 C. Thus, the example chassis 110 is more compact than the known heat-pipe based design but has better thermal conductivity than the known vapor chamber design. Due to the minimal thermal resistance of the heat sink section, the temperature of the CPU is lower than that of the known heat-pipe based design.

As used in this application, the terms “component,” “module,” “system,” or the like, generally refer to a computer-related entity, either hardware (e.g., a circuit), a combination of hardware and software, software, or an entity related to an operational machine with one or more specific functionalities. For example, a component may be, but is not limited to being, a process running on a processor (e.g., digital signal processor), a processor, an object, an executable, a thread of execution, a program, and/or a computer. By way of illustration, both an application running on a controller, as well as the controller, can be a component. One or more components may reside within a process and/or thread of execution, and a component may be localized on one computer and/or distributed between two or more computers. Further, a “device” can come in the form of specially designed hardware; generalized hardware made specialized by the execution of software thereon that enables the hardware to perform specific function; software stored on a computer-readable medium; or a combination thereof.

The terminology used herein is for the purpose of describing particular embodiments only, and is not intended to be limiting of the invention. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art. Furthermore, terms, such as those defined in commonly used dictionaries, should be interpreted as having a meaning that is consistent with their meaning in the context of the relevant art, and will not be interpreted in an idealized or overly formal sense unless expressly so defined herein.

While various embodiments of the present invention have been described above, it should be understood that they have been presented by way of example only, and not limitation. Although the invention has been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application. Thus, the breadth and scope of the present invention should not be limited by any of the above described embodiments. Rather, the scope of the invention should be defined in accordance with the following claims and their equivalents.

What is claimed is:

1. A thermally absorbing chassis operable to enclose electronic components, the chassis comprising:
a heat sink section having an interior surface and an exterior surface, the interior surface configured for contact with a heat-generating electronic device;
a lateral hollow compartment near the interior surface; and
a coolant contained in the hollow compartment.

2. The chassis of claim 1, further comprising cooling fins extending from the exterior surface of the heat sink section.

3. The chassis of claim 1, wherein the heat sink section includes a plate soldered over a groove together to define the lateral hollow compartment and the interior surface.

4. The chassis of claim 3, wherein the plate is a first thermally conductive material and the heat sink section is a second, different thermally conductive material.

5. The chassis of claim 1, wherein the coolant is one of water or refrigerant.

6. The chassis of claim 1, wherein the heat sink section is fabricated from aluminum or an aluminum alloy.

7. The chassis of claim 1, wherein the hollow compartment has opposite ends, one of the opposite ends located near a section of the interior surface that contacts the heat generating electronic device.

8. The chassis of claim 1, wherein the electronic components are for operation of a 5G mobile communication system.

9. An electronic component, comprising:
a printed circuit board having a heat-generating device; and
a chassis enclosing the printed circuit board, the chassis having side walls, a base supporting the printed circuit board, and a heat sink section including an interior surface in thermal contact with the heat-generating device, an opposite exterior surface, and a chamber holding coolant in proximity to the interior surface.

10. The electronic component of claim 9, wherein the heat sink section includes cooling fins extending from the exterior surface of the heat sink section.

11. The electronic component of claim 9, wherein the heat sink section includes a plate soldered over a groove together to define the chamber.

12. The electronic component of claim 11, wherein the plate is a first thermally conductive material and the heat sink section is a second, different thermally conductive material.

13. The electronic component of claim 9, wherein the coolant is one of water or refrigerant.

14. The electronic component of claim 9, wherein the heat sink section is fabricated from aluminum or an aluminum alloy.

15. The electronic component of claim 9, wherein the chamber has opposite ends, one of the opposite ends located near a section for contact with the heat generating device.

16. The electronic component of claim 9, wherein the heat generating device is for a 5G telecommunication system.

17. A method of fabricating a heat absorbing chassis for a fan-less component, the method comprising:
fabricating a heat sink block having an interior surface and an exterior surface;
forming a groove in the interior surface;
attaching a plate over the groove to form an interior compartment; and
filling the interior compartment with coolant.

18. The method of claim 17, wherein the fabricating of the heat sink block is performed via die casting and wherein the heat sink block includes fins attached to the exterior surface.

19. The method of claim 17, wherein the coolant is one of water or refrigerant.

20. The method of claim 17, wherein the heat sink block is aluminum or an aluminum alloy and the plate is copper.
